(19) United States
(12) Patent Application Publication
(10) Pub. No.: US 2013/0048351 A1
(43) Pub. Date: Feb. 28, 2013

(54) ELECTRONIC PACKAGE STRUCTURE AND METHOD FOR MANUFACTURING SAME

(71) Applicant: JUN-YI XIAO, Zhongshan City (CN)

(72) Inventor: JUN-YI XIAO, Zhongshan City (CN)

(73) Assignees: HON HAI PRECISION INDUSTRY CO., LTD., Tu-Cheng (TW); AMBIT MICROSYSTEMS (ZHONGSHAN) LTD., Zhongshan City (CN)

(21) Appl. No.: 13/280,359

(22) Filed: Oct. 25, 2011

(30) Foreign Application Priority Data
Aug. 24, 2011 (CN) 201110247329.4

(51) Int. Cl. H05K 1/09; H05K 3/30; H05K 1/02

(52) U.S. Cl. 174/257; 174/260; 29/841

(57) ABSTRACT

An exemplary electronic package structure includes a substrate configured with a solder pad, a metal support element, an electronic component connected to the solder pad, and an encapsulation body. The metal support element is located between the solder pad and the electronic component. As a result, a gap is defined between the substrate and the electronic component. A height of the gap is equal to a height of the solder pad plus a height of the metal support element. The encapsulation body encapsulates the electronic component together with the substrate and the gap is completely filled with material of the encapsulation body.

### BACKGROUND

1. Technical Field

The present disclosure generally relates to electronic package structures and methods for manufacturing such electronic package structures.

2. Description of Related Art

In electronics, a ceramic package is popularly employed for large size electronic components, such as crystal oscillators. A gap with a size less than 10 microns is generally formed between the electronic component and a substrate when the electronic component is mounted on the substrate by a surface mounting technology (SMT) process. During a molding process for packaging the electronic component on the substrate, molten encapsulating material (such as resin) fails to flow into the gap due to the small size of the gap. As a result, during a subsequent reflow soldering process, the package module with the electronic component may easily short or become cracked due to the gap between the bottom of the electronic component and the substrate.

Therefore, a need exists in the industry to overcome the described problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a cross-sectional view of an electronic package structure of an exemplary embodiment of the disclosure.

FIG. 2 is a cross-sectional view of positioning a plurality of metal support elements on a plurality of solder pads on a substrate, according to another exemplary embodiment of the disclosure.

FIG. 3 is similar to FIG. 2, but showing coating tin solder on surfaces of the metal support elements.

FIG. 4 is similar to FIG. 3, but showing mounting an electronic component on the plurality of metal support elements.

### DETAILED DESCRIPTION

The disclosure is illustrated by way of example and not by way of limitation in the figures of the accompanying drawings, in which like reference numerals indicate similar elements. It should be noted that references to “an” or “one” embodiment in this disclosure are not necessarily to the same embodiment, and such references can mean “at least one” embodiment.

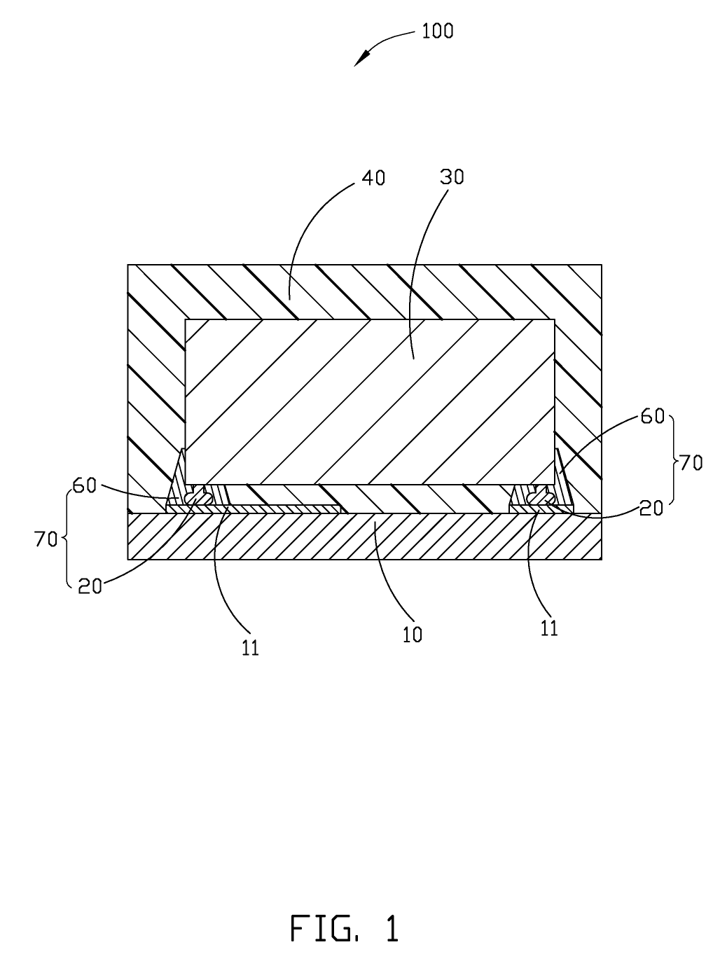

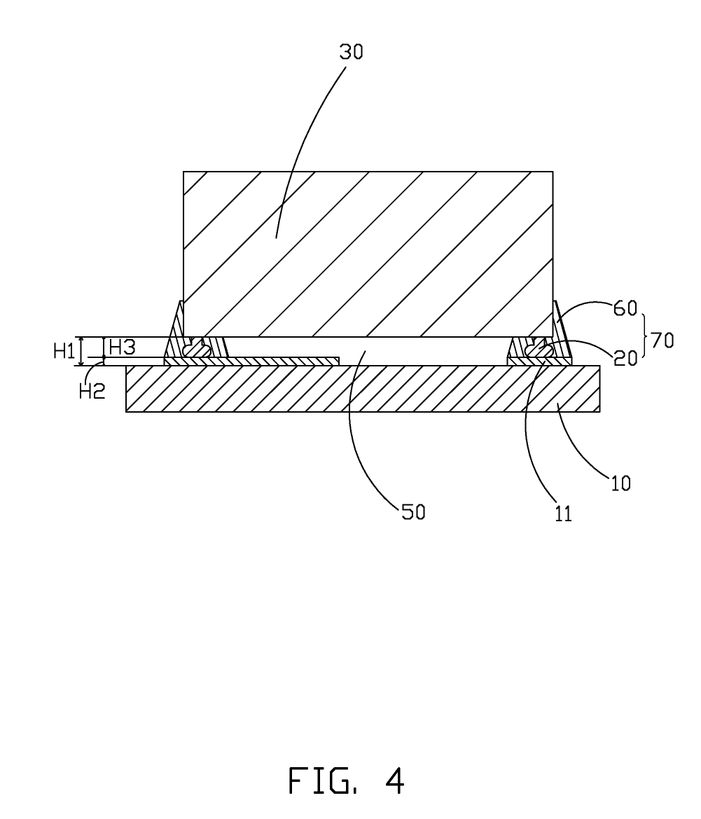

With reference to FIGS. 1-4, an electronic package structure 100 comprises a substrate 10, a plurality of metal support elements 20, an electronic component 30 and an encapsulation body 40. The substrate 10 comprises a plurality of solder pads 11 connected to the electronic component 30. The plurality of metal support elements 20 are located between the plurality of solder pads 11 and the electronic component 30. As a result, a gap 50 is defined between the substrate 10 and the electronic component 30. A height H1 of the gap 50 is equal to a height H2 of the solder pads plus a height H3 of the metal support elements 20 (see FIG. 4). The encapsulation body 40 encapsulates the electronic component 30 together with the substrate 10, and fills the gap 50 completely. In the embodiment, the encapsulation body 40 is an epoxy resin.

During mounting the electronic component 30 on the substrate 10 by a surface mounting technology (SMT) process, the height H1 of the gap 50 does not change when tin solder 60 between the electronic element 30 and the substrate 10 melts, because the electronic component 30 is supported by the metal support elements 20 that do not be melt during the SMT process. During a subsequent molding process, molten material for forming the encapsulation body 40 flows into the gap 50 and fills the gap 50 completely without forming any voids or air bubbles between the electronic component 30 and the substrate 10. This enables the electronic package structure 100 to achieve good performance.

In the embodiment, the height H3 of the metal support elements 20 is about 30˜70 microns, which ensures that the encapsulation body 40 fills the gap 50 completely.

In the embodiment, the metal support elements 20 are made of copper. Alternatively, the metal support elements 20 can be made of gold or aluminum.

Typically, a surface of each of the metal support elements 20 is coated with the tin solder 60. Each of the metal support elements 20 is integrated with the tin solder 60 to form a solder portion 70, to support and secure the electronic component 30 on the substrate 10. When the gap 50 is filled with the encapsulation body 40, the electronic element 30 is securely electrically connected to the substrate 10 due to the tin solder 60.

A method of fabricating the electronic package structure 100 comprises steps as follows.

The plurality of solder pads 11 are provided on the substrate 10 to electrically connect the substrate 10 to the electronic component 30.

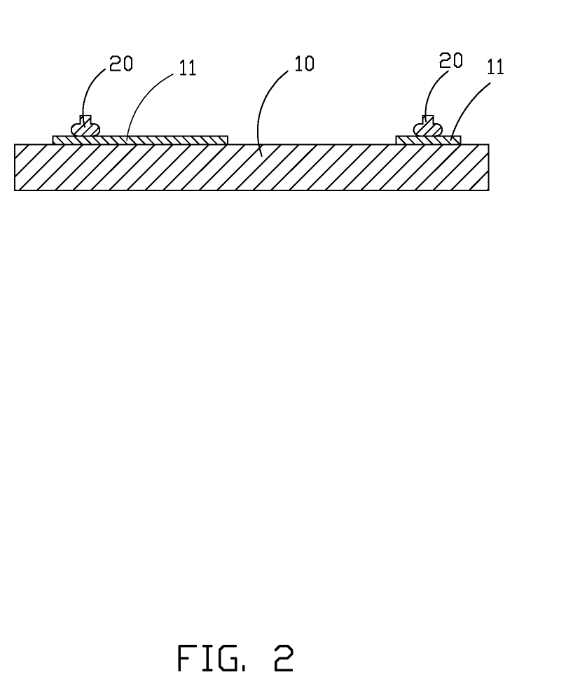

Referring to FIG. 2, the plurality of metal support elements 20 are positioned on the plurality of solder pads 11, respectively. In the embodiment, the plurality of metal support elements 20 are formed on the solder pads 11 of the substrate 10 by wire bonding technology, which can improve productivity when manufacturing the electronic package structure 100.

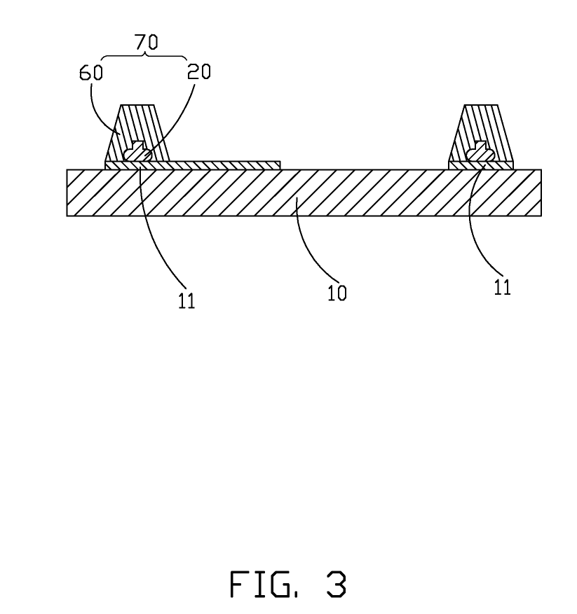

Referring to FIG. 3, the surfaces of the metal support elements 20 are coated with the tin solder 60 to form the solder portions 70.

Referring to FIG. 4, the electronic component 30 is mounted on the metal support elements 20 by an SMT process. In this process, the gap 50 is defined between the electronic component 30 and the substrate 10. The height H1 of the gap 50 does not change when the tin solder 60 melts, due to the support of the metal support elements 20.

Referring to FIG. 1, the electronic component 30 is encapsulated on the substrate 10 to form an encapsulation body 40, with the gap 50 fully filled with the encapsulation body 40.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. An electronic package structure, comprising:
a substrate provided with a plurality of solder pads;
a plurality of metal support elements located on the plurality of solder pads;
an electronic component located on the metal support elements; and
an encapsulation body encapsulating the electronic component together with a surface of the substrate, wherein a gap is defined between the electronic component and the substrate with a height of the gap equal to a height of the solder pads plus a height of the metal support elements, and the gap is fully filled with the encapsulation body.

2. The electronic package structure of claim 1, wherein the metal support elements are made of copper.

3. The electronic package structure of claim 1, wherein the metal support elements are made of aluminum.

4. The electronic package structure of claim 1, wherein the metal support elements are made of gold.

5. The electronic package structure of claim 1, wherein the height of each of the metal support elements is about 30˜70 microns.

6. The electronic package structure of claim 1, wherein a surface of each of the metal support elements is coated with tin solder.

7. A method of manufacturing an electronic package structure, the method comprising:
providing a plurality of solder pads on a substrate;
positioning a plurality of metal support elements on the plurality of solder pads, respectively;
mounting an electronic component on the plurality of metal support elements, wherein a gap is defined between the electronic component and the substrate, with a height of the gap equal to a height of the solder pads plus a height of the metal support elements; and
encapsulating the electronic component on the substrate to form an encapsulation body, with the gap completely filled with the encapsulation body.

8. The method of claim 7, further comprising coating tin solder on a surface of each of the metal support elements.

9. The method of claim 7, wherein the metal support elements are formed on the solder pads by wire bonding technology.

10. An electronic package structure, comprising:
a substrate provided with a plurality of solder pads;
a plurality of metal support elements located on the plurality of solder pads;
an electronic component located on the metal support elements; and
an encapsulation body encapsulating the electronic component together with a surface of the substrate, wherein a gap is defined between the electronic component and the substrate with a height of the gap equal to a height of the solder pads plus a height of the metal support elements, and the gap is completely filled with material of the encapsulation body.
